(19) United States
(12) Patent Application Publication
(10) Pub. No.: US 2015/0211114 A1
(43) Pub. Date: Jul. 30, 2015

(54) BOTTOM PUMP AND PURGE AND BOTTOM OZONE CLEAN HARDWARE TO REDUCE FALL-ON PARTICLE DEFECTS

(71) Applicant: Applied Materials, Inc., Santa Clara, CA (US)

(72) Inventors: Abhijit KANGUDE, Santa Clara, CA (US); Sanjeev BALUJA, Campbell, CA (US); Juan Carlos ROCHA-ALVAREZ, San Carlos, CA (US); Daemian RAJ, Fremont, CA (US)

(21) Appl. No.: 14/593,068

(22) Filed: Jan. 9, 2015

Related U.S. Application Data
(60) Provisional application No. 61/933,432, filed on Jan. 30, 2014.

(51) Int. Cl. C23C 16/44; C23C 16/455; C23C 16/48

(52) U.S. Cl. CPC C23C 16/4412; C23C 16/48; C23C 16/455; C23C 16/4401

(57) ABSTRACT

Embodiments described herein generally relate to preventing contaminant deposition within a semiconductor processing chamber and removing contaminants from a semiconductor processing chamber. Bottom purging and pumping prevents contaminant deposition below a pedestal heater or exhausts contaminants from below the pedestal, respectively. Bottom purging prevents contaminants from depositing below the pedestal and provides for an exhaust from the processing chamber to be located substantially coplanar with a substrate being processed. Bottom pumping removes contaminants present below the pedestal from the processing chamber. Specifically, embodiments described herein relate to purging and pumping via a pedestal bellows and/or equalization port.

### CROSS REFERENCE TO RELATED APPLICATIONS

This application claims benefit of U.S. provisional patent application No. 61/933,432, filed Jan. 30, 2014, the entirety of which is herein incorporated by reference.

### BACKGROUND

1. Field

Embodiments described herein generally relate to preventing contaminant deposition within a semiconductor processing chamber and removing contaminants from a semiconductor processing chamber. More specifically, embodiments described herein relate to bottom pump and purge and bottom ozone clean hardware to reduce fall-on particle defects.

2. Description of the Related Art

Ultraviolet (UV) semiconductor processing chambers and processes may be utilized for forming silicon containing films on a semiconductor substrate. These films include low-k and ultra low-k dielectrics with k values less than about 4.0 and 2.5, respectively. Ultra low-k dielectric materials may be fabricated by incorporating voids within a low-k dielectric matrix to form a porous dielectric material. Methods of fabricating porous dielectrics typically involve forming a precursor film containing two components: a porogen (typically an organic material, such as a hydrocarbon) and a structuring or dielectric material (e.g., a silicon containing material). Once the precursor film is formed on the substrate, the porogen component may be removed, leaving a structurally intact porous dielectric matrix or oxide network.

The UV processing chambers utilized to form low-k and ultra low-k dielectrics may have non-uniform gas flows through the chamber during the UV curing process to remove the porogen. As a result, the UV processing chamber may become coated with porogen materials, including the coating of windows that permit UV light to reach the substrate and other regions of the UV processing chamber which experience non-uniform gas flows. For example, regions of the UV processing chamber below the heater (e.g., the pedestal) often become contaminated with porogen residue.

The build-up or porogen residue (generally an organic contaminant) on UV chamber components may result in an unevenly cured film across the surface of the substrate. With time, the porogen residue reduces the effectiveness of subsequent UV porogen removal processes by reducing the effective UV intensity available at the substrate. Moreover, the build-up of excessive residues in the UV chamber are a source of particulate defects on the substrate. Accordingly, thermally unstable organic materials (resulting from porogens used to increase porosity) need to be removed from the UV processing chamber. Increased cleaning frequency and time to remove the porogen residue undesirably results in reduced throughput.

Accordingly, there is a need in the art for an improved UV processing chamber and method of using the same.

### SUMMARY

In one embodiment, and apparatus for processing a substrate is provided. The apparatus comprises a processing chamber body which defines a processing region. A moveable pedestal assembly is disposed within the processing region and an ultraviolet radiation source is coupled to the chamber body. A light transmissive window is disposed between the ultraviolet radiation source and the pedestal assembly. A first port is disposed through the chamber body at a first region which is substantially coplanar with a processing position of the pedestal assembly and a second port is disposed through a sidewall of the chamber body at a second region. The second region is located below the first region.

In another embodiment, and apparatus for processing a substrate is provided. The apparatus comprises a processing chamber body which defines a processing region. A moveable pedestal assembly is disposed within the processing region. The pedestal assembly has a pedestal assembly surface, a stem and a bellows assembly that surrounds at least a portion of the stem. The bellows assembly is disposed outside the processing volume. An ultraviolet radiation source is coupled to the chamber body and a light transmissive window is disposed between the ultraviolet radiation source and the pedestal assembly. A first port is disposed through the chamber body at a first region which is substantially coplanar with a processing position of the pedestal assembly. A second port is disposed through a bottom of the chamber body at a second region which circumferentially surrounds the stem.

In yet another embodiment, a twin volume processing chamber is provided. The chamber comprises a chamber body defining a first inner volume and a second inner volume. A first pedestal assembly is disposed within the first inner volume, a first ultraviolet radiation source is coupled to the chamber body adjacent the first inner volume and a first light transmissive window is disposed between the first ultraviolet radiation source and the first pedestal assembly. A second pedestal assembly is disposed within the second inner volume, a second ultraviolet radiation source is coupled to the chamber body adjacent the second inner volume and a second light transmissive window is disposed between the second ultraviolet radiation source and the second pedestal assembly. A first port is disposed within a central region of the chamber body between the first inner volume and the second inner volume. The first port is substantially coplanar with a processing position of the first pedestal assembly and the second pedestal assembly. A second port is disposed within the central region of the chamber body below the first port. The first port and the second port volumetrically couple the first inner volume and the second inner volume.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 illustrates a cross-sectional view of a processing system according to one embodiment described herein.

FIG. 2 illustrates a side view of a portion of the processing system of FIG. 1.

FIG. 3 illustrates a plan view of the processing system of FIG. 1 with UV sources removed to illustrate interior components.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments described herein generally relate to preventing contaminant deposition within a semiconductor processing chamber and removing contaminants from a semiconductor processing chamber. Bottom pumping and purging substantially prevents contaminant deposition below a pedestal assembly or exhausts contaminants from below the pedestal assembly. Bottom purging substantially prevents contaminants from depositing below the pedestal assembly and provides for an exhaust from the processing chamber to be located substantially coplanar with a substrate being processed. Bottom pumping removes contaminants present below the pedestal assembly from the processing chamber. Specifically, embodiments described herein relate to purging and pumping via a pedestal bellows and/or equalization port.

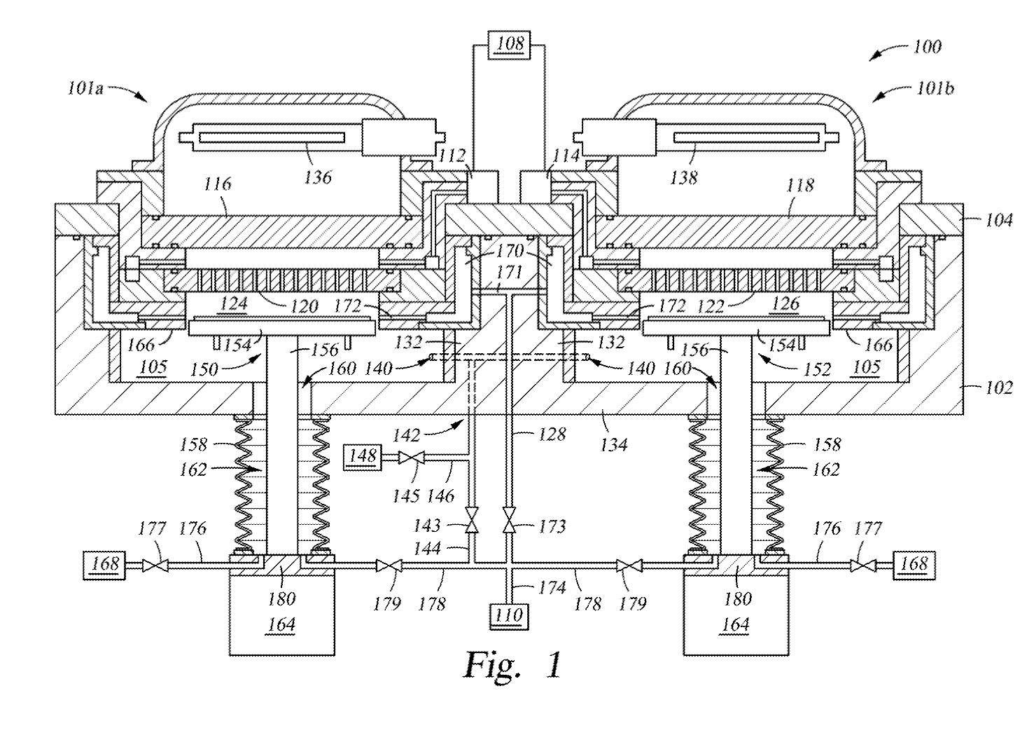

FIG. 1 illustrates a cross-sectional view of a twin volume processing system 100. The system 100 illustrates an exemplary embodiment of a 300 mm PRODUCER® processing system, commercially available from Applied Materials, Inc., of Santa Clara, Calif. The embodiments described herein may also be advantageously employed on the PRODUCER® NANOCURE™ and PRODUCER® ONYX™ systems, both available from Applied Materials, Inc., of Santa Clara, Calif., and other suitably adapted processing systems, including those from other manufacturers.

The processing system 100 includes two processing chambers 101a, 101b which are substantially identical to each other. The processing chambers 101a, 101b share a chamber body 102 and a chamber lid 104. The processing chambers 101a, 101b are mirror images of one another about a central plane 129.

The chamber 101a defines a processing volume 124 for processing a single substrate. The chamber 101a includes a UV transparent window 116 and a UV transparent gas distribution showerhead 120 disposed above the processing volume 124. The chamber 101b defines a processing volume 126 for processing a single substrate. The chamber 101b includes a UV transparent window 118 and a UV transparent gas distribution showerhead 122 disposed above the processing volume 126.

The chambers 101a, 101b share a gas panel 108 and a vacuum pump 110. The chamber 101a is coupled to the gas panel 108 via an input manifold 112 and the chamber 101b is coupled to the gas panel 108 via an input manifold 114. A first UV light source 136 is coupled to the chamber 101a via the lid 104. The window 116 is disposed between the first UV light source 136 and the processing volume 124. A second UV light source 138 is coupled to the chamber 101b via the lid 104. The window 118 is disposed between the second UV light source 138 and the processing volume 126.

The processing system 100 also includes pedestal assemblies 150, 152 which are disposed in the chambers 101a, 101b, respectively. Liners 166 are disposed within each of the chambers 101a, 101b and surround each of the pedestal assemblies 150, 152. The pedestal assembly 150 is disposed at least partially within the chamber 101a and the pedestal assembly 152 is disposed at least partially within the chamber 101b. The liner 166 shields the chamber body 102 from processing chemistry in the processing volumes 124, 126. An exhaust plenum 170 radially surrounds the processing volumes 124, 126 and a plurality of apertures 172 are formed through the liners 166 connecting the exhaust plenum 170 and the processing volumes 124,126. The plurality of apertures 172 and at least a portion of the exhaust plenum 170 may be substantially coplanar with supporting surfaces 154 of the pedestal assemblies 150, 152.

The vacuum pump 110 is in fluid communication with the exhaust plenum 170 so that the processing volumes 124, 126 can be pumped out through the plurality of apertures 172 and the exhaust plenum 170. The exhaust plenum 170 is coupled to a common exhaust plenum 171 which extends through the chamber bottom 134 to a pump conduit 174. The pump conduit 174 is coupled to the vacuum pump 110 to facilitate the pumping of gases from the common exhaust plenum 171. A common exhaust valve 173 is disposed on the pump conduit 174 between the common exhaust plenum 171 and the pump 110. The common exhaust valve 173 may be opened or closed depending on desired pumping operation.

The supporting surfaces 154 of the pedestal assemblies 150, 152 are disposed within the processing volumes 124, 126. The supporting surfaces 154 are generally a top portion of the pedestal assemblies 150, 152 configured to support a substrate during processing. A bottom region 105 of the chambers 101a, 101b is defined between the chamber bottom 134 and the supporting surfaces 154 of the pedestal assemblies 150, 152. Each pedestal assembly 150, 152 has a stem 156 that extends from a bottom surface of each pedestal assembly 150, 152 through a bottom 134 of the chamber body 102. The stems 156 are coupled to a respective motor 164 which is configured to independently raise and lower each the pedestal assemblies 150, 152.

Pedestal bellows ports 160 are formed in the bottom 134 of the chamber body 102. The pedestal bellows ports 160 extend through the bottom 134 of the chamber body 102. Each pedestal bellows port 160 has a diameter larger than a diameter of the stem 156 and circumscribes each stem 156 where the stem 156 extends through the bottom 134 of the chamber body 102. The pedestal bellows ports 160 circumferentially surround the stems 156.

A bellows assembly 158 is disposed around each pedestal bellows port 160 to prevent vacuum leakage outside the chamber body 102. The bellows assemblies 158 circumscribe and enclose a portion of each stem 156 disposed outside the chamber body 102. The bellows assemblies 158 are coupled between an exterior surface of the bottom 134 of the chamber body 102 and a base member 180. The base member 180 may house the motor 164 and a portion of the stem 156 which is coupled to the motor 164.

The bellows assemblies 158 may be formed from a metallic or metallized material and be configured to form a gas flow channel 162. The gas flow channel 162 is defined as a region between the stem 156 and the bellows assembly 158 extending from the pedestal bellows port 160 to the base member 180. As such, the gas flow channel 162 forms a hollow cylindrically shaped passage between the bellows assembly 158 and the stem 156. The gas flow channel 162 is fluidly coupled between the bottom region 105 and an exhaust conduit 178. The exhaust conduit 178 extends from the gas flow channel 162 through the base member 180 to the pump conduit 174. A valve 179 is disposed on the exhaust conduit 178 between the gas flow channel 162 and the pump conduit 174. When the valve 179 is closed, pumping via the exhaust plenum 170 may proceed and when the valve 179 is open, pumping via the pedestal bellows port 160 may proceed. When the valve 179 is open, the common exhaust valve 173 may be closed to enhance pumping of the bottom region 105 via the pedestal bellows port 160.

In one embodiment of a pumping process, the bottom regions 105 of each chamber 101a, 101b is pumped via the pedestal bellows port 160. Gases and particles present in the bottom region 105 travel through the pedestal bellows port 160, the gas flow channel 162 and the exhaust conduit 178 to the pump 110. In this embodiment, the common exhaust valve 173 is closed and the valve 179 is open so that the pump is in fluid communication with the bottom region 105. The pumping via the pedestal bellows port 160 is performed during a chamber cleaning process, for example, when the chamber is idle and not processing a substrate. In one embodiment, the pumping via each pedestal bellows port 160 is performed at a flow rate of between about 10 standard liters per minute (slm) and about 50 slm, such as about 30 slm. An inert gas may also be provided to the chambers 101a, 101b during the pedestal bellows pumping process. For example, argon is provided to both chambers 101a, 101b from the gas panel 108 with a flow rate of between about 5 slm and about 25 slm, such as about 15 slm for each chamber 101a, 101b. It is believed that the argon provided via the gas panel 108 enables more efficient cleaning and pumping of the bottom region 105.

In one embodiment, a gas source 168 is fluidly coupled to the bottom region 105 via the gas flow channel 162 and the pedestal bellows port 160. The gas source 168 may be configured to deliver an inert gas or a cleaning gas to the bottom region 105. Although schematically shown as being in close physical proximity with the system 100, the gas source 168 is generally a remote gas source located remotely from the system 100. The gas source 168 is coupled to a conduit 176 which extends from the gas source 168 through the base member 180. The conduit 176 is in fluid communication with the gas flow channel 162. A valve 177 is disposed on the conduit 176 between the gas source 168 and the base member 180.

In one embodiment, an inert gas, or purge gas, is provided to the bottom region 105. In operation, the purge gas is provided to the bottom region 105 along a flow pathway from the gas source 168, through the conduit 176 with the valve 177 opened, the gas flow channel 162 and the pedestal bellows port 160. The purge gas is provided from the gas source 168 during processing of a substrate in the chambers 101a, 101b. Suitable purge gases include inert gases, such as helium, neon and argon. However, other unreactive gases may also be utilized. In one embodiment, the argon is provided with a flow rate of between about 1 slm and about 40 slm, such as about 20 slm. The argon flow may be divided between the chambers 101a, 101b such that about 10 slm or argon is provided to the bottom region 105 of each chamber 101a, 101b via the pedestal bellows port 160.

It is believed that flowing the purge gas during processing of a substrate prevents particles and contaminants from falling below the supporting surface 154 and depositing on the surface of the chambers 101a, 101b which define the bottom region 105. During purging via the pedestal bellows port 160, pumping of the chambers 101a, 101b proceeds via the exhaust plenum 170 and the pump 110. The plurality of apertures 172 and at least a portion of the exhaust plenum 170 are substantially coplanar with the supporting surface 154. Pumping via the exhaust plenum 170 draws the purge gas from the bottom region 105. In this embodiment, the purge gas and contaminants are exhausted from the chambers 101a, 101b without the contaminants falling below the supporting surface 154.

In another embodiment, a cleaning gas is provided to the bottom region 105 via the gas source 168. In one embodiment, ozone is utilized as the cleaning gas, however, it is contemplated that other cleaning gases may also be utilized. In one embodiment, the ozone is generated remotely by a remote plasma system or other similar apparatus. In another embodiment, ozone is provided to the bottom region 105 along the same pathway as the purge gas described above. In this embodiment, the chambers 101a, 101b are pressurized and heated to facilitate dissociation of the ozone into O⁻ and O₂. In the cleaning process (which is performed separate of substrate processing), the elemental oxygen reacts with hydrocarbons and carbon species (porogens) that are present on the surfaces that define the bottom region 105 to form a volatile gas, such as carbon monoxide and carbon dioxide, which are then exhausted from the chambers 101a, 101b.

In one example of an ozone cleaning process, oxygen is exposed to UV radiation at selected wavelengths to generate ozone in-situ. For example, the light sources 136, 138 are energized to emit UV radiation with a wavelength of between about 184.9 nm and about 153.7 nm. The UV radiation is absorbed by the ozone, which dissociates into both oxygen gas as well as elemental oxygen to clean the bottom region 105.

The system 100 also includes an equalization port 140 which is disposed through a center wall 132 of the system. The center wall 132 divides the chambers 101a, 101b and defines at least a portion of the bottom region 105. The equalization port 140 is an opening which is in fluid communication with the bottom regions 105 of each chamber 101a, 101b. The equalization port 140 may be formed in the center wall 132 or through a different region of the body 102 defining the bottom region 105. The equalization port 140 is disposed substantially below the supporting surface 154 and the exhaust plenum 170. The equalization port 140 extends from the bottom region 105 of each chamber 101a, 101b through the center wall 132 and enables the bottom region 105 of each chamber 101a, 101b to be in fluid communication with one another.

A conduit 144 extends from the equalization port 140 through the center wall 132 and exits the bottom 134 of the chamber body 102 at an exit port 142. The conduit 144 fluidly couples the equalization port 140 with the conduit 178. A valve 143 is disposed on the conduit 144 between the exit port 142 and the conduit 178. Thus, when the valve 143 is open, the bottom region 105 is in fluid communication with the pump 110.

In one example, the bottom region 105 is exhausted by an equalization port 140 pumping process. The equalization port 140 pumping process is performed while the chamber is idle, such as during an idle cleaning process. To enable pumping via the equalization port 140, the valve 173 is closed and the valve 143 is opened. As such, the pump 110 is in fluid communication with the bottom region 105 via the conduit 144 and the equalization port 140. As a result of the valve 173 being closed, exhausting of the chambers 101a, 101b proceeds via the equalization port 140 and not through the exhaust plenum 170.

During the equalization port 140 pumping process, the pump 110 exhausts gases and contaminants from the bottom region 105 through the equalization port 140 and conduit 144. In one embodiment, gases and contaminants are pumped from the bottom region 105 via the equalization port 140 with a flow rate of between about 10 slm and about 50 slm, such as about 30 slm. An inert gas may also be provided to the chambers 101a, 101b during the equalization port 140 pumping process. For example, argon is provided to both chambers 101a, 101b from the gas panel 108 with a flow rate of between about 5 slm and about 25 slm, such as about 15 slm per each chamber 101a, 101b. It is believed that the argon provided via the gas panel 108 enables more efficient cleaning and pumping of the bottom region 105. Pumping via the equalization port 140 removes undesirable contaminants from the bottom region 105 without utilizing the exhaust plenum 170, which provides increased functionality of the system 100.

In one embodiment, a gas source 148 is fluidly coupled to the bottom regions 105 via the conduit 144 and the equalization port 140. The gas source 148 may be configured to deliver an inert gas or a cleaning gas to the bottom regions 105. Although schematically shown as being in close physical proximity with the system 100, the gas source 148 is generally a remote gas source located remotely from the system 100. The gas source 148 is coupled to a conduit 146 which extends from the gas source 148 to the conduit 144. A valve 145 is disposed on the conduit 146 between the gas source 148 and the conduit 144.

In one embodiment, an inert gas, or purge gas, is provided to the bottom regions 105. In operation, the purge gas is provided to the bottom regions 105 along a flow pathway from the gas source 148, through the conduit 146 with the valve 145 opened, the conduit 144 and the equalization port 140. The purge gas is provided from the gas source 148 during an idle cleaning process. Suitable purge gases include inert gases, such as helium, neon and argon. However, other unreactive gases may also be utilized. In one embodiment, the argon is provided with a flow rate of between about 10 slm and about 50 slm, such as about 30 slm. The argon flow may be divided between the chambers 101a, 101b such that about 15 slm or argon is provided to the bottom region 105 of each chamber 101a, 101b via the equalization port 140.

It is believed that flowing the purge gas during an idle clean process agitates and stirs up particles and contaminants which may be present on the surfaces defining the bottom regions 105. During purging via the equalization port 140, pumping of the chambers 101a, 101b proceeds via the exhaust plenum 170 and the pump 110. Pumping via the exhaust plenum 170 draws the purge gas from the bottom region 105. In this embodiment, the purge gas and contaminants are exhausted from the chambers 101a, 101b without the contaminants redepositing below the supporting surface 154 or within the bellows assemblies 158.

In another embodiment, a cleaning gas is provided to the bottom regions 105 via the gas source 148. In one embodiment, ozone is utilized as the cleaning gas, however, it is contemplated that other cleaning gases may also be utilized. In one embodiment, the ozone is generated remotely by a remote plasma system or other similar apparatus. In another embodiment, ozone is provided to the bottom regions 105 along the same pathway as the purge gas described above. The ozone purging process may proceed as described with regard to the ozone purging via the pedestal bellows ports 160.

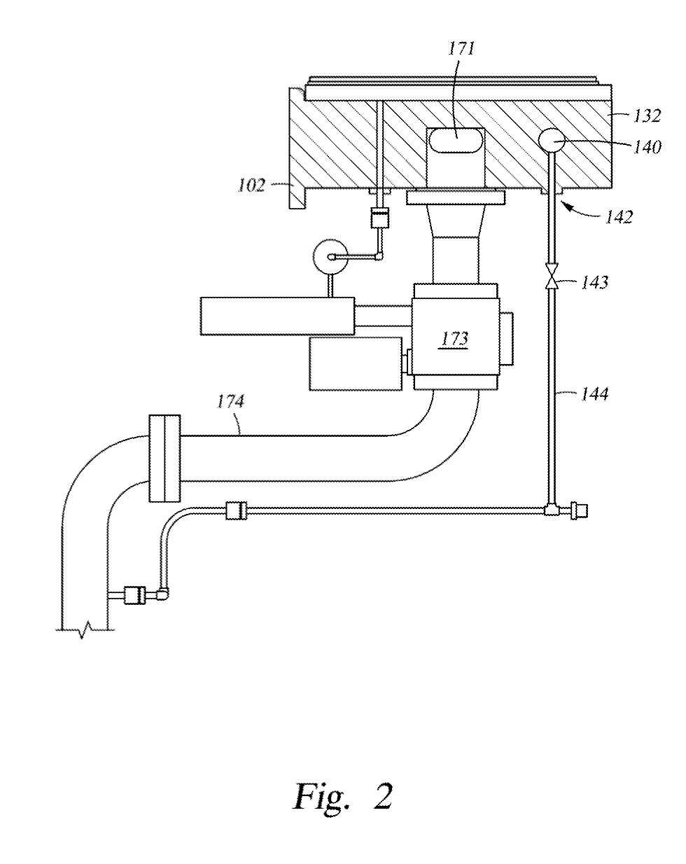

FIG. 2 illustrates a side view of a portion of the system 100 of FIG. 1. As illustrated, the system 100 is sectioned along line 128 of FIG. 1. In this view, a lid housing the UV light source is omitted. The center wall 132 of the body 102 illustrates the positions of the common exhaust plenum 171 and the equalization port 140. The valve 173 is disposed on the exhaust conduit 174 which extends from the common exhaust plenum 171 to the pump 110 (not shown).

The equalization port 140 is formed through a laterally adjacent region of the center wall 132. The conduit 144 extends from the equalization port 140 and exits the center wall 132 at the exit port 142. The valve 143 is disposed on the conduit 144 between the exit port 142 and where the conduit 144 couples to the exhaust conduit 174. The conduit 144 couples to the exhaust conduit 174 between the valve 173 and the pump 110.

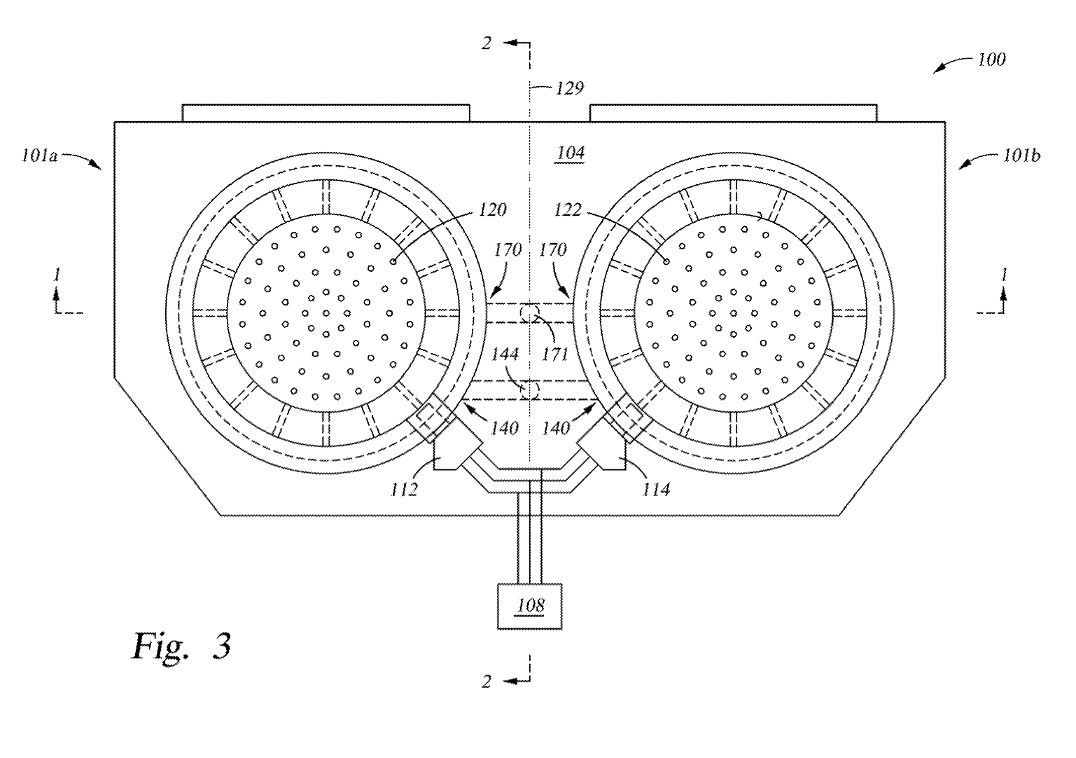

FIG. 3 illustrates a plan view of the system 100 of FIG. 1. In this view, a lid housing the UV light source is omitted and the lid 104 and showerheads 120, 122 are visible. The common exhaust plenum 171 is centrally located within the system 100 and the exhaust plenum 170 is disposed adjacent to the common exhaust plenum 171. The common exhaust plenum 171 is disposed along a central plane 129. The chambers 101a, 101b are substantially identical mirror images along the central plane 129. The conduit 140 is laterally offset from the central plane 129. The equalization port 140 is fluidly coupled to the conduit 144. This illustration is intended to provide the spatial relation between the conduit 144/equalization port 140 and the exhaust plenum 170/common exhaust plenum 171.

In the embodiments described above, contaminants, such as particles, are either exhausted from the chambers by the pumping processes or substantially prevented from depositing on chamber surfaces by the purging processes. It is contemplated that one or more of the pumping and purging processes may be utilized alone or in combination with one another to reduce the undesirable effects of particles within a semiconductor processing chamber. The embodiments described herein are especially useful for UV semiconductor processing chambers where porogen particles are present. It is also contemplated that the embodiments described herein may be advantageously employed on dual chamber processing systems as well as single chamber processing systems. The processing systems may include elements of either the pedestal bellows pumping/purging or the equalization port pumping/purging, or may include both the pedestal bellows pumping/purging and the equalization port pumping/purging on a single processing system.

While the foregoing is directed to embodiments of the present disclosure, other and further embodiments of the disclosure may be devised without departing from the basic scope thereof, and the scope thereof is determined by the claims that follow.

1. An apparatus for processing a substrate, comprising:
a processing chamber body defining a processing region, the processing chamber body having:
an exhaust port disposed through the processing chamber body at a first region, the exhaust port being in fluid communication with the processing region and the first region being disposed adjacent the processing region; and
a pump/purge port disposed through the chamber body at a second region, wherein the second region is located below the first region;
a pedestal assembly disposed within the processing region;
an ultraviolet radiation source coupled to the chamber body; and
a light transmissive window disposed between the ultraviolet radiation source and the pedestal assembly.

2. The apparatus of claim 1, further comprising a first conduit coupled between the exhaust port and a pump.

3. The apparatus of claim 2, wherein a first valve is disposed on the first conduit between the exhaust port and the pump.

4. The apparatus of claim 3, wherein a second conduit couples the pump/purge port to the first conduit between the first valve and the pump.

5. The apparatus of claim 4, wherein a second valve is disposed on the second conduit between the pump/purge port and the first conduit.

6. The apparatus of claim 5, wherein a purge gas source is coupled to the second conduit between the pump/purge port and the second valve.

7. An apparatus for processing a substrate, comprising:
a processing chamber body defining a processing region, the processing chamber body having:
an exhaust port disposed through the processing chamber body at a first region, the first region being substantially coplanar with a processing position of the pedestal assembly; and
a pump/purge port disposed through a bottom of the processing chamber body at a second region;
a pedestal assembly disposed within the processing region, the pedestal assembly comprising a substrate supporting surface, a stem disposed through the second region, and a bellows assembly surrounding at least a portion of the stem, wherein the second region circumferentially surrounds the stem and the bellows assembly is disposed outside the processing volume;
an ultraviolet radiation source coupled to the chamber body; and
a light transmissive window disposed between the ultraviolet radiation source and the pedestal assembly.

8. The apparatus of claim 7, wherein a gas flow channel extends from the pump/purge port between the stem and the bellows assembly.

9. The apparatus of claim 8, wherein a conduit couples the exhaust port to a pump.

10. The apparatus of claim 9, wherein a first valve is disposed on the first conduit between the exhaust port and the pump.

11. The apparatus of claim 10, wherein a second conduit couples the gas flow channel to the first conduit between the first valve and the pump.

12. The apparatus of claim 11, wherein a second valve is disposed on the second conduit between the gas flow channel and the first conduit.

13. The apparatus of claim 7, wherein a purge gas source is coupled to the gas flow channel between the pump/purge port and the second conduit.

14. A twin volume processing apparatus, comprising:
a chamber body defining a first inner volume and a second inner volume;
a first pedestal assembly disposed within the first inner volume;
a first ultraviolet radiation source coupled to the chamber body adjacent the first inner volume;
a first light transmissive window disposed between the first ultraviolet radiation source and the first pedestal assembly;
a second pedestal assembly disposed within the second inner volume;
a second ultraviolet radiation source coupled to the chamber body adjacent the second inner volume; and
a second light transmissive window disposed between the second ultraviolet radiation source and the second pedestal assembly;
wherein a first port is disposed within a central region of the chamber body between the first inner volume and the second inner volume, the first port being substantially coplanar with a processing position of the first pedestal assembly and the second pedestal assembly; and
wherein a second port is disposed within the central region of the chamber body below the first port, and the first port and the second port fluidly couple the first inner volume and the second inner volume.

15. The apparatus of claim 14, wherein a first conduit couples the first port to a pump, the pump being configured to exhaust both the first inner volume and the second inner volume.

16. The apparatus of claim 15, wherein a first valve is disposed on the first conduit between the first port and the pump.

17. The apparatus of claim 16, wherein a second conduit couples the second port to the first conduit between the first valve and the pump.

18. The apparatus of claim 16, wherein a second valve is disposed on the second conduit between the second port and the first conduit.

19. The apparatus of claim 17, wherein a purge gas source is coupled to the second conduit between the pump/purge port and the second valve.

20. The apparatus of claim 14, further comprising:
a first bellows assembly surrounding a first stem of the first pedestal assembly and a second bellows assembly surrounding a second stem of the second pedestal assembly, wherein the first and second bellows assemblies are disposed outside the chamber body;
a third port disposed through a bottom of the chamber body where the first pedestal assembly stem enters the first inner volume;
a first gas flow channel disposed between the first stem and the first bellows assembly, the first gas flow channel extending from the third port to an outlet;
a fourth port disposed through the bottom of the chamber body where the second pedestal assembly stem enters the second inner volume; and
a second gas flow channel disposed between the second stem and the second bellows assembly, the second gas flow channel extending from the fourth port to the outlet.
